(19) United States
(12) Patent Application Publication
(10) Pub. No.: US 2016/0329885 A1
(43) Pub. Date: Nov. 10, 2016

(54) SIGNAL PROCESSING CIRCUIT

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: JIN-SHAN MA, Shenzhen (CN); YANG LIU, Shenzhen (CN)

(21) Appl. No.: 14/811,551

(22) Filed: Jul. 28, 2015

(30) Foreign Application Priority Data
May 8, 2015 (CN) 201510231697.8

(51) Int. Cl. H03K 5/159

(52) U.S. Cl. CPC H03K 5/159; H03K 2005/0015

(57) ABSTRACT

A signal processing circuit is connected between a first external circuit and a second external circuit. The signal processing circuit includes a signal input module and a signal processing module. The signal input module receives signal from the first external circuit. The processing module processes the signals received from the signal input module.

### FIELD

The subject matter herein generally relates to a signal processing circuit.

### BACKGROUND

Time delay circuits are used to protect circuits of a server or a computer from inrush current. However, the time delay circuits may delay a power off signal when the circuits stop operating, which will make data in the circuits disorderly or lost.

### BRIEF DESCRIPTION OF THE DRAWING

Implementations of the present technology will now be described, by way of example only, with reference to the attached figure.

FIG. 1 is a block diagram of an embodiment of a signal processing circuit.

FIG. 2 is a block diagram of a signal processing module of the signal processing circuit of FIG. 1.

FIG. 3 is a circuit diagram of an embodiment of a signal processing circuit.

### DETAILED DESCRIPTION

Numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” when utilized, means “including, but not necessarily limited to”; it specifically indicates open-ended inclusion or membership in the so-described combination, group, series and the like.

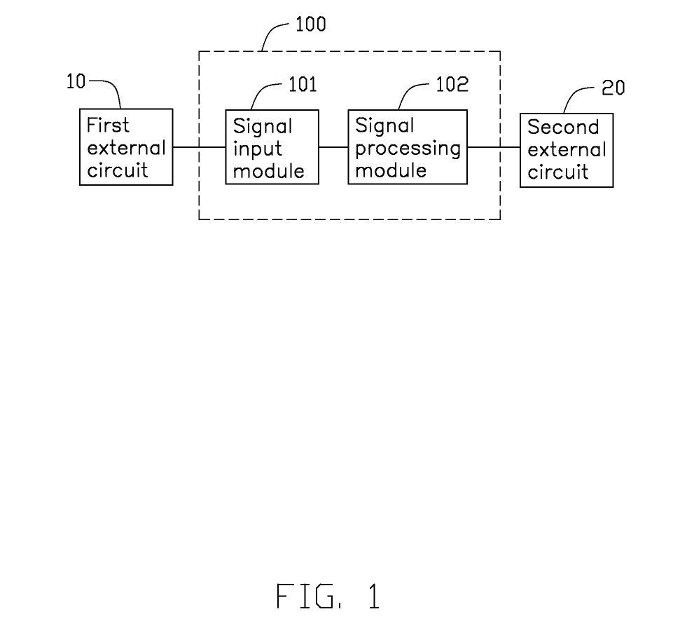

FIG. 1 shows an embodiment of a signal processing circuit 100. The signal processing circuit 100 can comprise a signal input module 101 and a signal processing module 102. The signal input module 101 is coupled to a first external circuit 10 to receive a first signal or a second signal. The signal processing module 102 is configured to process the first signal and the second signal and outputs a signal processed to a second external circuit 20.

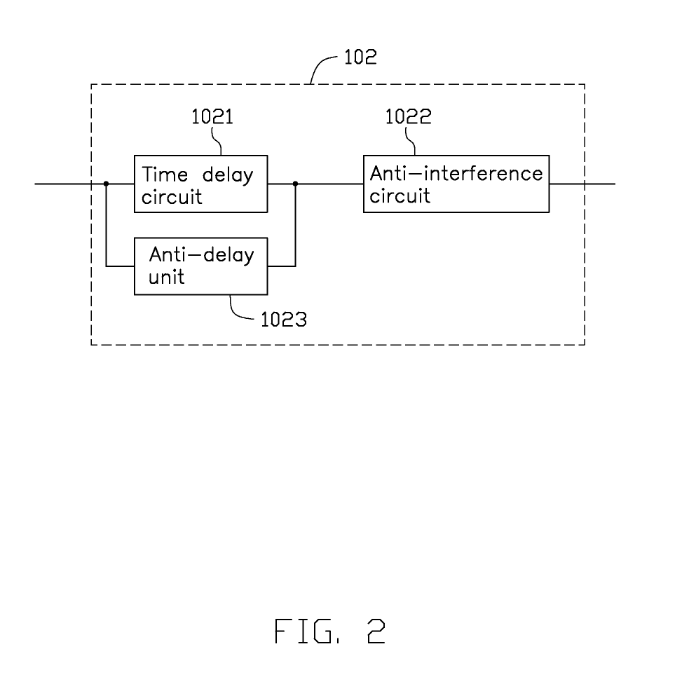

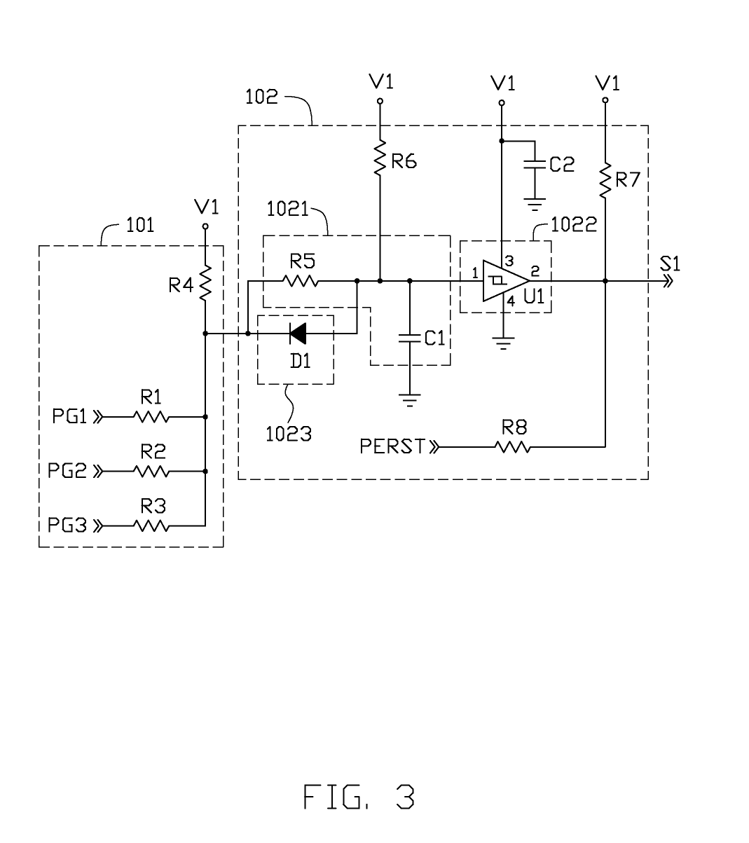

FIG. 2 and FIG. 3 illustrate an embodiment of the signal processing circuit 100. The signal processing module 102 can comprise a time delay circuit 1021, an anti-interference circuit 1022, and an anti-delay unit 1023. The time delay circuit 1021 is configured to delay the first signal and the second signal. The anti-interference circuit 1022 is configured to reduce interference to the first signal and the second signal. The anti-delay unit 1023 is configured to eliminate the time delay of the first signal and the second signal. The first signal is output to the second external circuit 20 through the time delay circuit 1021. The second signal is output to the second external circuit 20 through the time delay circuit 1021 and the anti-delay unit 1023 in that order.

In the embodiment, the time delay circuit 1021 can comprise a resistor R5 and a capacitor C1. The anti-interference circuit 1022 can comprise a Schmitt trigger U1. The anti-delay unit 1023 can comprise a diode D1.

The signal processing module 101 can comprise a first signal input PG1, a second signal input PG2, a third signal input PG3, and resistors R1-R4. The first signal input PG1 is coupled to a power terminal V1 through the resistor R1 and the resistor R4 in that order. The second signal input PG2 is coupled to the power terminal V1 through the resistor R2 and the resistor R4 in that order. The third signal input PG3 is coupled to the power terminal V1 through the resistor R3 and the resistor R4 in that order. The power terminal V1 is configured to supply an auxiliary voltage.

The signal processing module 102 can comprise resistors R5-R8, the capacitor C1, a capacitor C2, the Schmitt trigger U1, the diode D1, and a reset signal terminal PERST. A first terminal of the resistor R5 is coupled to the power terminal V1 through the resistor R4. A second terminal of the resistor R5 is coupled to the power terminal V1 through the resistor R6. The second terminal of the resistor R5 is also coupled to ground through the capacitor C1. The diode D1 and the resistor R5 are coupled in parallel. An anode of the diode D1 is coupled to the second terminal of the resistor R5. A cathode of the diode D1 is coupled to the first terminal of the resistor R5. The resistor R1 is coupled to the capacitor C1 through the cathode of the diode D1 and the anode of the diode D1 in that order. The second terminal of the resistor R5 is coupled to an input 1 of the Schmitt trigger U1. An output 2 of the Schmitt trigger U1 is coupled to a signal terminal S1 of the second external circuit 20. A power terminal 3 of the Schmitt trigger U1 is coupled to the power terminal V1. A ground terminal 4 of the Schmitt trigger U1 is grounded. The reset signal terminal PERST is coupled to the signal terminal S1 through the resistor R8. The signal terminal S1 of the second external circuit 20 is coupled to the power terminal V1 through the resistor R7. The diode D1 can be a Schottky diode. In other embodiments, the anti-delay unit 1023 can be other electronic elements which control the capacitor C1 to discharge rapidly according to the second signal, such as a bipolar junction transistor or a field effect transistor.

In the embodiment, the first external circuit 10, the second external circuit 20, and the signal processing circuit 100 are applied in an electronic device. The first external circuit 10 is configured to output a first signal or a second signal. The second external circuit 20 is configured to enable the electronic device to operate. When the signal terminal S1 of the second external circuit 20 is at a high level, the electronic device is turned on. When the signal terminal S1 of the second external circuit 20 is at a low level, the electronic device is turned off. The reset signal terminal PERST is configured to input a signal to reset the electronic device.

In the embodiment, the first signal is at high level, such as logic 1. The second signal is at a low level, such as logic 0. The first to third signal inputs PG1-PG3 are configured to output the first signal or the second signal synchronously.

In other embodiments, the signal input module 101 can comprise at least one signal input. The signal input module 101 receives the first signal or the second signal through the at least one signal input.

When the signal from the first to third signal inputs PG1-PG3 turns into high level, the time delay circuit 1021 delays the signal, and the Schmitt trigger U1 outputs the signal delayed to the signal terminal S1 of the second external circuit 20. A first terminal of the capacitor C1 coupled to the Schmitt trigger U1 is at a high level. The electronic device is turned on.

When the signal from the first to third signal inputs PG1-PG3 turns into low level, the capacitor C1 discharges rapidly through the diode D1. The first terminal of the capacitor C1 turns into low level. The input 1 of the Schmitt trigger U1 turns into low level and the signal terminal S1 turns into low level. The electronic device is turned off

While the disclosure has been described by way of example and in terms of the embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A signal processing circuit coupled to a first external circuit and a second external circuit, the signal processing circuit comprising:
a signal input module configured to receive a first or second signal from the first external circuit;
a signal processing module comprising a time delay circuit and an anti-delay unit, wherein the time delay circuit is configured to delay the first signal and the second signal, the anti-delay unit is configured to eliminate the delay of the second signal, the signal processing module is configured to transmit the first signal to the second external circuit via the time delay circuit, and the signal processing module is configured to transmit the second signal to the second external circuit via the time delay circuit and the anti-delay unit, in that order.

2. The signal processing circuit as claim 1, wherein the signal input module comprises a first signal input and a first resistor, the time delay circuit comprises a second resistor and a first capacitor, the first signal input is grounded through the first resistor, the second resistor, and the first capacitor in that order.

3. The signal processing circuit as claim 2, wherein the anti-delay unit comprises a diode, the diode and the second resistor are coupled in parallel, the first resistor is coupled to the first capacitor through a cathode of the diode and an anode of the diode in that order.

4. The signal processing circuit as claim 3, wherein the first signal input is coupled to a power terminal through the first resistor and a third resistor in that order, the signal input module further comprises a second signal input and a fourth resistor, the second signal input is coupled to the power terminal through the fourth resistor and the third resistor in that order.

5. The signal processing circuit as claim 4, wherein the signal input module further comprises a third signal input and a fifth resistor, the third signal input is coupled to the power terminal through the fifth resistor and the third resistor in that order.

6. The signal processing circuit as claim 2, further comprising an anti-interference circuit configured to reduce interference for the first signal and the second signal, wherein the time delay circuit is coupled to the second external circuit through the anti-interference circuit.

7. The signal processing circuit as claim 6, wherein the anti-interference circuit comprises a Schmitt trigger, an input of the Schmitt trigger is coupled between the second resistor and the first capacitor, an output of the Schmitt trigger is coupled to the second external circuit.
